(19) United States
(12) Patent Application Publication
(10) Pub. No.: US 2021/0298212 A1
(43) Pub. Date: Sep. 23, 2021

(54) CONDUCTIVE SHIELD FOR AN ELECTRONIC DEVICE

(71) Applicant: Apple Inc., Cupertino, CA (US)

(72) Inventors: Kevin K. MAYER, Menlo Park, CA (US); Alex Chun Lap YEUNG, San Francisco, CA (US); Chunwei YU, Saratoga, CA (US); Judith C. SEGURA, San Francisco, CA (US); Lee B. HAMSTRA, Menlo Park, CA (US); John V. ABRAM, San Francisco, CA (US)

(21) Appl. No.: 17/033,477

(22) Filed: Sep. 25, 2020

Related U.S. Application Data
(60) Provisional application No. 62/991,468, filed on Mar. 18, 2020.

(51) Int. Cl. H05K 9/00; H05K 7/20

(52) U.S. Cl. CPC H05K 9/0054; H05K 7/20418; H05K 7/20963

(57) ABSTRACT

An electronic device that includes a circuit board and a shield designed to cover the circuit board is disclosed. The shield can provide radio frequency shielding, thermal energy dissipation, and desense mitigation. The shield provides added structural benefits. For example, the thermal assembly can be made with a non-metal material, such as graphite. Further, the thermally assembly may include multiple graphite layers secured by adhesive layers. Additionally, the shield can rely upon adhesives/tapes to adhere to a metal wall located on a perimeter of the circuit board. In this manner, the shield can provide a compliant body that conforms to the position and location of the metal wall, account for tolerance variations in the metal wall, and thus prevent bending of the metal wall, as opposed to using rigid metal bodies. Based on the adhesive properties, the shield requires no holes for fasteners.

### CROSS-REFERENCE TO RELATED APPLICATIONS

The present application claims the benefit of U.S. Provisional Application No. 62/991,468, entitled “CONDUCTIVE SHIELD FOR AN ELECTRONIC DEVICE,” filed Mar. 18, 2020, the content of which is incorporated herein by reference in its entirety for all purposes.

### FIELD

The following description relates to electronic devices. In particular, the following description relates to shields used to protect circuitry from electromagnetic interference and other noises, as well as provide a thermal dissipation path for heat generated by the circuitry. The shields described herein are formed by non-rigid materials, which enhance the compliant properties of the shields.

### BACKGROUND

Shields can be used to block noise from interfering with circuitry. Some noise shields include a relatively rigid metal, such as sheet metal. However, while metal provides noise-blocking and thermal conductivity properties, the rigidity of metal layers (including sheet metal and other rigid metals) can cause certain issues. For example, in order to secure a shield to a circuit board, several holes are formed in the shield (including the metal layer), with each hole receiving a fastener. These holes define voids in the metal layer(s), which can permit noise to pass through the shield and extend to one or more components located on the circuit board.

Additionally, when the metal layer is secured to another structure located on the circuit board, other issues may occur. For example, when the fastener secures the shield to the circuit board, the fastener provides a force to the metal layer(s). When a (vertical) height difference exists between the fastener and the other structure, the metal layer(s) applies a bending moment to the structure. The force provided by the bending moment can cause the structure to bend or warp, and possibly break away from the circuit board, thereby reducing the noise mitigation capabilities of the shield. In order to offset the height differences, one or more heat-dissipating layers of the shield can be removed. However, with fewer heat-dissipating layers, the shield can no longer dissipate thermal energy as efficiently.

### SUMMARY

In one aspect, an electronic device is described. The electronic device may include a circuit board that carries a processing circuit. The electronic device may further include a shield that covers the processing circuit. The shield may include an electrically conductive layer configured to block radio interference generated by the processing circuit. The shield may further include a thermal assembly coupled with the electrically conductive layer. The thermal assembly can be configured to dissipate thermal energy generated by the processing circuit. The thermal assembly may include a first thermally conductive layer. The thermal assembly may further include an adhesive layer coupled with the first thermally conductive layer. The thermal assembly may further include a second thermally conductive layer coupled with the adhesive layer. In some embodiments, the first thermally conductive layer and the second thermally conductive layer may include a non-metal material.

In another aspect, an electronic device is described. The electronic device may include a display configured to present visual information. The electronic device may further include an enclosure coupled with the display. The enclosure may define an internal volume configured to carry components. The components may include a circuit board that carries a processing circuit. The components may include an antenna electrically coupled to the circuit board. The components may further include a metal wall located on the circuit board. The components may further include a shield. The shield may include a conductive tape adhered to the metal wall. The conductive tape may be configured to shield the antenna from radio frequency shield generated by the processing circuit. The shield may further include a thermal assembly adhered with the conductive tape. The thermal assembly may provide a thermal dissipation path for thermal energy generated by the processing circuit.

In another aspect, a shield suitable for use in an electronic device is described. The shield may include a first electrically conductive tape. The shield may further include a first electrically conductive tape adhered to the first electrically conductive tape. The shield may further include a thermal assembly positioned between the first electrically conductive tape and the second electrically conductive tape. The thermal assembly may include a first thermally conductive layer. The thermal assembly may further include a first adhesive layer adhered to the first thermally conductive layer. The thermal assembly may further include a second thermally conductive layer adhered to the first adhesive layer. The thermal assembly may further include a second adhesive layer adhered to the second thermally conductive layer. In some embodiments, the first thermally conductive layer and the second thermally conductive layer may include a non-metal material.

Other systems, methods, features and advantages of the embodiments will be, or will become, apparent to one of ordinary skill in the art upon examination of the following figures and detailed description. It is intended that all such additional systems, methods, features and advantages be included within this description and this summary, be within the scope of the embodiments, and be protected by the following claims.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a front isometric view of an embodiment of an electronic device;

FIG. 2 illustrates a rear isometric view of the electronic device shown in FIG. 1;

FIG. 3 illustrates a plan view of the electronic device shown in FIG. 1, showing various internal components of the electronic device;

FIG. 4 illustrates an isometric view of the circuit board and the shield, in accordance with some described embodiments;

FIG. 5 illustrates an exploded view of the shield, in accordance with some described embodiments;

FIG. 6 illustrates a cross sectional view of the electronic device, showing the shield connected to the wall;

FIG. 7 illustrates a cross sectional view of the electronic device, showing the thermal energy dissipation properties of the shield;

FIG. 8 illustrates an exploded view of an alternate embodiment of a shield, in accordance with some described embodiments;

FIGS. 9 and 10 illustrate thermal assemblies with different configurations of adhesive layers;

FIG. 11 illustrates a flowchart showing a method for assembling a shield, in accordance with some described embodiments; and

FIG. 12 illustrates a block diagram of an electronic device, in accordance with some described embodiments.

Those skilled in the art will appreciate and understand that, according to common practice, various features of the drawings discussed below are not necessarily drawn to scale, and that dimensions of various features and elements of the drawings may be expanded or reduced to more clearly illustrate the embodiments of the present invention described herein.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting such that other embodiments may be used, and changes may be made without departing from the spirit and scope of the described embodiments.

The following disclosure relates to a shield for use with electronic devices, such as portable electronic device, including smartphones, tablet computing devices, and laptops (as non-limiting examples). The shield is designed to cover, or overlay, a circuit board of an electronic device, as well as the components on the circuit board. Based upon its position, the shield can provide several benefits. For example, the shield may include conductive adhesives, such as electrically conductive tapes, that shield wireless components (e.g., antennae and wireless circuitry) in the electronic device from radio frequency (“RF”) interference, including electromagnetic interference (“EMI”), generated by one or more components on the circuit board. The electrically conductive tape can also mitigate desense for the wireless components. Additionally, the shield may include a thermal assembly that includes thermally conductive layers designed to draw away thermal energy generated by one or more components located on the circuit board. The electrically conductive tape may include a metal (e.g., copper) or metals, while the thermal assembly may use multiple layers formed from a material (or materials) of relatively high thermal conductivity. For example, at least some layers of the thermal assembly may include graphite, which provides enhanced thermal energy dissipation and less rigidity.

While the electrically conductive tape may include metal, both the electrically conductive tape and the thermally conductive layers are generally non-rigid bodies (as compared to sheet metal, for example). For instance, the electrically conductive tape may be flexible in a manner similar to that of adhesive tapes commonly known in the art. Also, based on adhesive properties of the electrically conductive tape, the shield can secure with a structure located on the circuit board, such as a metal wall (or metal perimeter), thereby forming a cage (based on the shield and the metal wall) to prevent propagation of RF interference generated by one or more components on the circuit board. In this manner, the shield, including its components and layers, may not require any openings, or through holes, as the adhesive properties, and not fasteners, are used to secure the shield with the metal wall. As a result, the shield can define a body with a continuous surface area that is unsusceptible, or at relatively less susceptible, to RF emission that would otherwise pass through the openings required for fasteners used to secure a traditional shield.

Moreover, by forming the thermal assembly and the electrically conductive tape from non-rigid bodies, the shield can provide a more compliant body. In this manner, the shield can more readily secure with the circuit board, and in particular, with the metal wall located on the circuit board. The compliant properties of the shield allow the shield to adjust and account for, or conform to, manufacturing variations of the metal wall due to the specified dimensional tolerances allowed for the metal wall. Also, the compliant properties of the shield allow the shield to easily bend, thereby minimizing or preventing an applied force by the shield to the metal wall (to which the shield is secured). As a result, the metal wall is less likely to undergo any bending, warping, or otherwise becoming damaged, and the likelihood of the metal wall breaking away from the circuit board is significantly reduced. In other words, the assembly process between the shield and the metal wall does not cause the metal wall to become non-compliant with respect to design specifications provided for the electronic device.

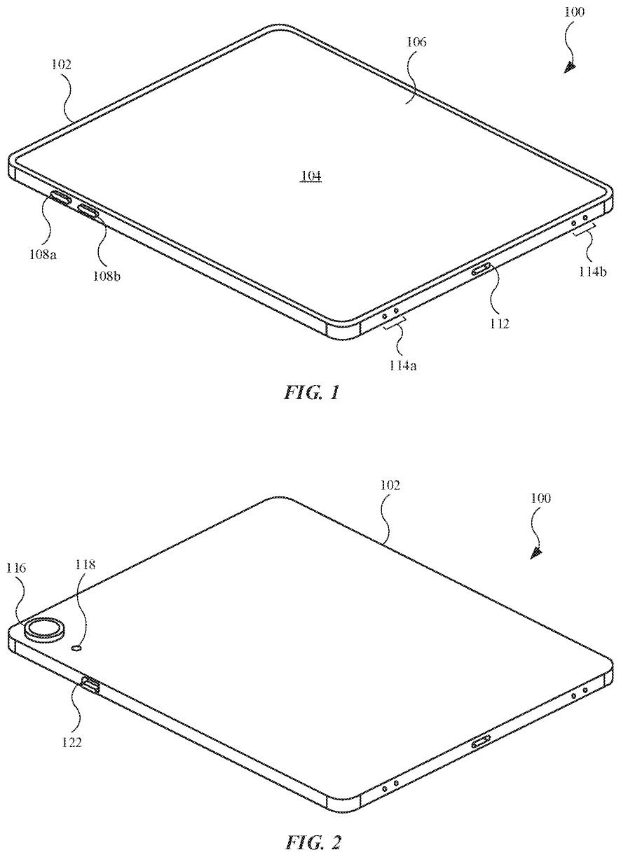

These and other embodiments are discussed below with reference to FIGS. 1-12. However, those skilled in the art will readily appreciate that the detailed description given herein with respect to these Figures is for explanatory purposes only and should not be construed as limiting.

FIG. 1 illustrates a front isometric view of an embodiment of an electronic device 100. In some embodiments, electronic device 100 is a laptop computing device or a desktop computing device. In the embodiment shown in FIG. 1, electronic device 100 is a mobile wireless communication device, such as a smartphone or a tablet computing device.

As shown, electronic device 100 may include an enclosure 102, or housing, that provides a protective body as well as defines an internal volume, or cavity, that receives several components, such as processing circuitry, memory circuitry, batteries, speaker modules, microphones, cameras, antennae, and flexible circuits that electrically couple together the aforementioned components. Enclosure 102 may include a metal, such as aluminum, steel (including stainless steel), or a metal alloy (as non-limiting examples). Alternatively, enclosure 102 may include non-metals, such as plastic or ceramic (as non-limiting examples).

Electronic device 100 may further include a display assembly 104. Display assembly 104 may include a touchscreen with capacitive touch input capabilities designed to receive user inputs and/or gestures. Electronic device 100 may further include a protective layer 106 that covers/overlays display assembly 104. Protective layer 106 can be formed from a transparent material, such as glass, plastic, or sapphire (as non-limiting examples). In order to receive additional inputs, electronic device 100 may further include a button 108a and a button 108b (each protruding through a respective opening of enclosure 102). Buttons 108a and 108b may be depressed to actuate a respective switch (not shown in FIG. 1) of electronic device 100.

Electronic device 100 may include a port 112 designed to electrically couple with an external source (not shown in FIG. 1), which may include an external data source and/or an external power source. Electronic device 100 may further include openings 114a and openings 114b, both formed in enclosure 102. Openings 114a and 114b may allow for acoustical energy transmission, in the form of audible sound, through enclosure 102. In this manner, electronic device 100 may include audio speakers and microphones (not shown in FIG. 1) that communicate with the external environment.

FIG. 2 illustrates a rear isometric view of electronic device 100 shown in FIG. 1. As shown, electronic device 100 may further include a camera assembly 116 (representative of one or more camera modules of electronic device 100). Electronic device 100 may further include a flash module 118 used to provide additional lighting during an image capture event by camera assembly 116. Electronic device 100 may further include a switch 122 that can be toggled by a user to change a configuration of electronic device 100, such as muting the aforementioned audio speakers. Each of the camera assembly 116, flash module 118, and switch 122 protrude through a respective opening of enclosure 102.

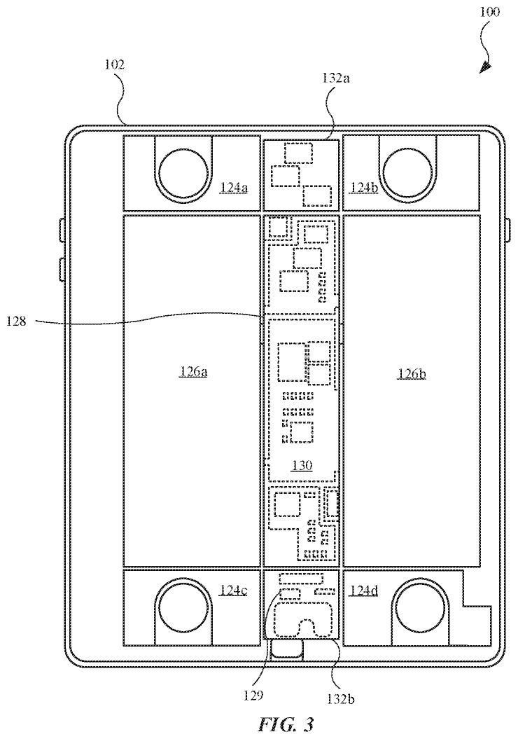

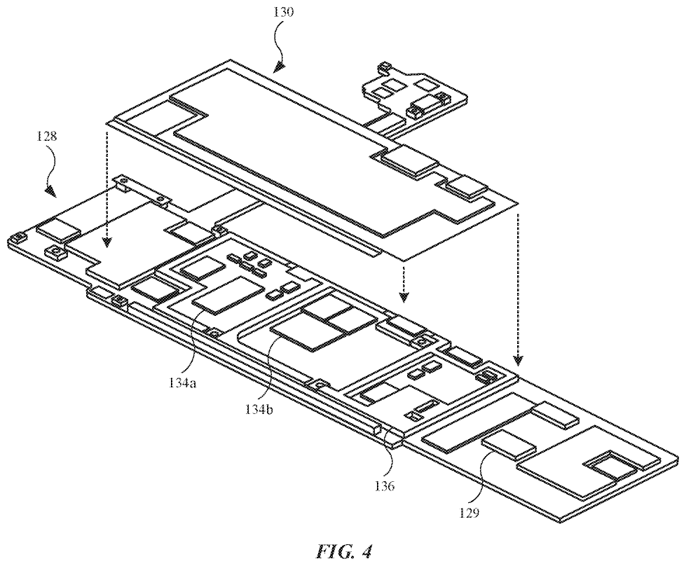

FIG. 3 illustrates a plan view of electronic device 100 shown in FIG. 1, showing various internal components of electronic device 100. For purposes of simplicity and illustration, display assembly 104 and protective layer 106 are removed. Also, several additional components, such as flexible circuitry, are not shown. Electronic device 100 may include several speaker modules, such as a speaker module 124a, a speaker module 124b, a speaker module 124c, and a speaker module 124d. Although not shown in FIG. 3, electronic device 100 may include additional speaker modules. Electronic device 100 may include multiple power supplies, or batteries, such as a power supply 126a and a power supply 126b. Electronic device 100 may further include a circuit board 128 (representative of one or more circuit boards) positioned between power supplies 126a and 126b. Circuit board 128 may carry several electronic components, such as processing circuits (e.g., central processing unit and a graphics processing unit), memory circuits, and other integrated circuits. Electronic device 100 may further include an antenna 129 (representative of one or more antennae) for wireless communication. Antenna 129 may support wireless communication through an industry standard, such as BLUETOOTH® or WI-FI®.

Electronic device 100 may further include a shield 130 that covers, or at least partially covers, circuit board 128. Accordingly, shield 130 may cover several aforementioned electronic components (shown as dotted lines) that are located on circuit board 128. Shield 130 is designed to provide RF shielding, including EMI shielding, thermal energy dissipation, and desense mitigation. The various features of shield 130 will be shown and described below. Additionally, electronic device 100 may further include a cowling 132a and a cowling 132b, each of which cover a portion of circuit board 128. Cowlings 132a and 132b can be used to secure several components, such as connectors, to enclosure 102. As shown in FIG. 3, antenna 129 is not covered by shield 130.

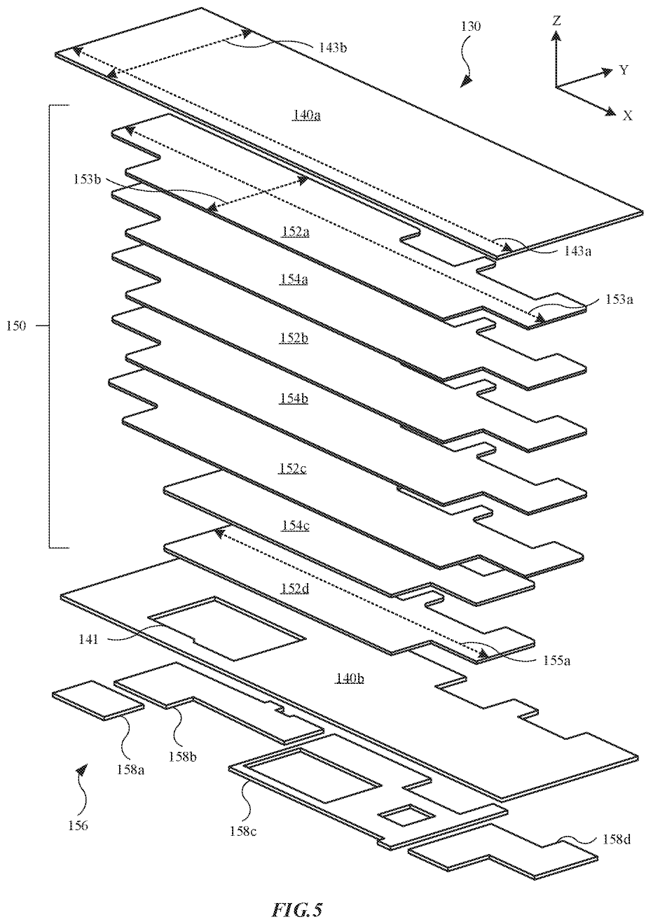

FIG. 4 illustrates an isometric view of circuit board 128 and shield 130, in accordance with some described embodiments. As shown, circuit board 128 includes a component 134a and a component 134b. At least one of components 134a and 134b may include a processing circuit, such as a central processing circuit, a graphics processing circuit, or a system-on-a chip, as non-limiting examples. In this regard, at least one of components 134a and 134b may generate RF interference, including EMI. However, shield 130 is designed to block and prevent EMI from reaching wireless components, such as antenna 129 and/or other wireless components of electronic device 100 (shown in FIG. 1).

Also, as shown, a wall 136 is disposed on circuit board 128. Wall 136 may include a metal wall formed from sheet metal, as a non-limiting example. Wall 136 defines a perimeter around at least some components located on circuit board 128, such as components 134a and 134b. Further, wall 136 may define a platform, or receiving surface, for shield 130. Further, shield 130 may include adhesive properties that allow shield 130 to adhere to wall 136. For example, shield 130 may include an adhesive tape. When shield 130 is adhered to wall 136, shield 130 and wall 136 may form a cage that blocks RF interference by components 134a and 134b from propagating throughout electronic device 100 (shown in FIG. 1). Moreover, due in part to the adhesive nature, shield 130 does not include openings, or through holes, that fully pass through the body defined by shield 130. As a result of being free of openings, shield 130 mitigates passageways for RF interference that would otherwise permit the RF interference through shield 130. Openings found in a traditional shield provide a means for connecting the traditional shield to a circuit board using fasteners. Also, once shield 130 is applied to wall 136, a cylindrical roller (not shown in FIG. 4) can apply pressure to shield 130 to ensure shield 130 is adhered to wall 136 in a desired manner.

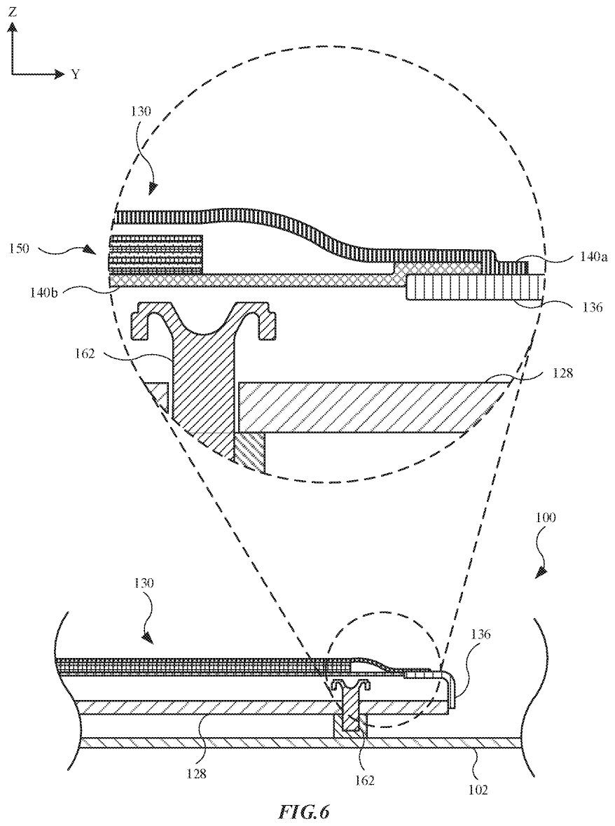

FIG. 5 illustrates an exploded view of shield 130, in accordance with some described embodiments. As shown, shield 130 includes a conductive layer 140a and a conductive layer 140b. Conductive layers 140a and 140b may define a first electrically conductive layer and a second electrically conductive layer, respectively. Conductive layers 140a and 140b may include one or more metals, such as copper. Also, in some embodiments, each of conductive layers 140a and the conductive layer 140b is also formed from an adhesive material, such as tape. In this manner, each of conductive layers 140a and 140b may define a first electrically conductive tape and a second electrically conductive tape, respectively. As a result, each of conductive layers 140a and 140b is a generally flexible body, as opposed to a rigid body (such as sheet metal).

Further, shield 130 may include a thermal assembly 150 formed from several thermally conductive layers. For example, thermal assembly 150 may include a thermally conductive layer 152a, a thermally conductive layer 152b, a thermally conductive layer 152c, and a thermally conductive layer 152d. Thermally conductive layers 152a, 152b, 152c, and 152d may be referred to as a first thermally conductive layer, a second thermally conductive layer, a third thermally conductive layer, and a fourth thermally conductive layer, respectively. In some embodiments, each of thermally conductive layers 152a, 152b, 152c, and 152d is formed from a non-metal material, such as graphite. Accordingly, each of thermally conductive layers 152a, 152b, 152c, and 152d may define a graphite layer. Due in part to material makeup of the graphite (e.g., fibers), each of thermally conductive layers 152a, 152b, 152c, and 152d may define relatively flexible layer, as opposed to a rigid metal layer.

In order to hold thermally conductive layers 152a, 152b, 152c, and 152d together, thermal assembly 150 includes several adhesive layers. For example, thermal assembly 150 may include an adhesive layer 154a, an adhesive layer 154b, and an adhesive layer 154c. Adhesive layers 154a, 154b, and 154c may be referred to as a first adhesive layer, a second adhesive layer, and a third adhesive layer, respectively. In some embodiments, each of adhesive layers 154a, 154b, and 154c includes a pressure sensitive adhesive designed to activate adhesive properties when a threshold force is applied. Generally, for n thermally conductive layers, thermal assembly 150 includes n−1 adhesive layers. Also, the thickness of each of adhesive layers 154a, 154b, and 154c is substantially small enough so as not prevent, or at least not substantially prevent, thermal energy passage through each individual layer.

Shield 130 may further include a structural layer 156 formed from one or more structural components. In some embodiments, structural layer 156 is formed from a polyester film that includes biaxially-oriented polyethylene terephthalate (“BoPET”), as a non-limiting example, BoPET may also be referred to as MYLAR®. Structural layer 156 may provide shield 130 with additional strength and stability, which can be particularly beneficial when metal layers are not integrated with shield 130. As shown, structural layer 156 is defined by a structural component 158a, a structural component 158b, a structural component 158c, and a structural component 158d. When assembled, the aforementioned structural components of structural layer 156 may be adhered to conductive layer 140b. In this regard, conductive layer 140b may include a two-sided adhesive layer.

Also, in order to accommodate certain components of circuit board 128 (shown in FIG. 4), shield 130 may include some regions that are void of material. For example, conductive layer 140b includes a cut out 141. Also, the layout of structural components 158a and 158b defines a void that is aligned with cut out 141. In this manner, when structural layer 156 is adhered to conductive layer 140b, a component (such as a system-on-a-chip) can pass through structural layer 156 and conductive layer 140b. Although shown but not labeled, structural component 158c includes multiple cut outs.

In some embodiments, the size and shape of the conductive layers (such as conductive layers 140a and 140b) may differ from that of the thermally conductive layers (such as the thermally conductive layers 152a, 152b, and 152c). For example, conductive layer 140a (representative of the size and shape of conductive layer 140b) includes a dimension 143a along the X-axis and a dimension 143b along the Y-axis, while thermally conductive layer 152a (representative of the size and shape of thermally conductive layers 152b and 152c) includes a dimension 153a along the X-axis and a dimension 153b along the Y-axis. The X-, Y-, and Z-axes shown in FIG. 5 refer to axes in a Cartesian coordinate system. As shown, dimensions 143a and 143b of conductive layer 140a are greater than dimensions 153a and 153b, respectively, of thermally conductive layer 152a. Accordingly, conductive layer 140a includes a greater surface area (defined along an X-Y plane) as compared to that of thermally conductive layer 152a. In other words, conductive layer 140a is larger than thermally conductive layer 152a. As a result, conductive layers 140a and 140b can extend laterally beyond thermally conductive layers 152a, 152b, and 152c, and adhere to a structure, such as wall 136 (shown in FIG. 4).

Also, in some embodiments, the size and shape of thermally conductive layers 152a, 152b, and 152c differs from that of thermally conductive layer 152d. For example, thermally conductive layer 152d includes a dimension 155a along the X-axis. Dimension 155a of thermally conductive layer 152d is less than dimension 153a of thermally conductive layer 152a. Accordingly, thermally conductive layer 152a includes a greater surface area (defined along an X-Y plane) as compared to that of thermally conductive layer 152d. In other words, thermally conductive layer 152a is larger than thermally conductive layer 152d. Also, by comparison, conductive layer 140a is larger than thermally conductive layer 152d. The difference in size and shape among thermally conductive layers 152a, 152b, 152c, and 152d allows thermal assembly 150 to provide more or less thermal energy dissipation capabilities as needed, while also accommodating some components of circuit board 128 (shown in FIG. 4). Regarding the latter, the difference in dimension of thermal assembly 150, and in turn shield 130, along the Z-axis may differ in some parts of thermal assembly 150 due in part do the different sizes and shapes of thermally conductive layers 152a, 152b, 152c, and 152d.

Shield 130 may provide several advantages over traditional shields. For example, the use of non-rigid bodies (i.e., graphite and no sheet metal) by shield 130 for thermal conductivity, can reduce the overall weight and cost of shield 130. Further, due in part to the use of graphite, the thermal energy transfer capabilities of shield 130 may increase, as compared to using a metal layer for thermal energy transfer. Finally, by eliminating openings, or through holes, shield 130 reduces EMI leaks and provides enhanced desense mitigation, as opposed to a shield that requires openings for fasteners.

FIG. 6 illustrates a cross sectional view of electronic device 100, showing shield 130 connected to wall 136. As shown, circuit board 128 is secured with enclosure 102 by a fastener 162. Further, as shown in the enlarged view, shield 130 is secured with wall 136 by conductive layers 140a and 140b being adhered to wall 136. In some embodiments (not shown), either one of conductive layers 140a and 140b adhered to wall 136. Based on their relatively larger size, both conductive layers 140a and 140b extend laterally (along the Y-axis, shown in FIG. 6) beyond thermal assembly 150 such that to conductive layers 140a and 140b extend and adhere to wall 136.

Additionally, based on the non-rigid properties of conductive layers 140a and 140b, both conductive layers 140a and 140b are compliant bodies that can conform to the position/location of wall 136. For example, prior to the assembly of shield 130 with wall 136, conductive layers 140a and 140b are both generally flat. However, subsequent to the assembly of shield 130 with wall 136, at least one of conductive layers 140a and 140b can bend or deform so that at least one of conductive layers 140a and 140b is positioned onto wall 136 without applying a bending force that bends or otherwise reshapes wall 136. As shown in FIG. 6, both conductive layers 140a and 140b conform to the location of wall 136, and wall 136 maintains its intended shape. Accordingly, wall 136 may be positioned at a height (along the Z-axis) so as to provide clearance for fastener 162, while at least one of conductive layers 140a and 140b adheres to wall 136 with relative ease. Further, the compliant characteristics of conductive layers 140a and 140b can account for dimensional variations of wall 136, if any, due to the tolerance specification allowed for wall 136.

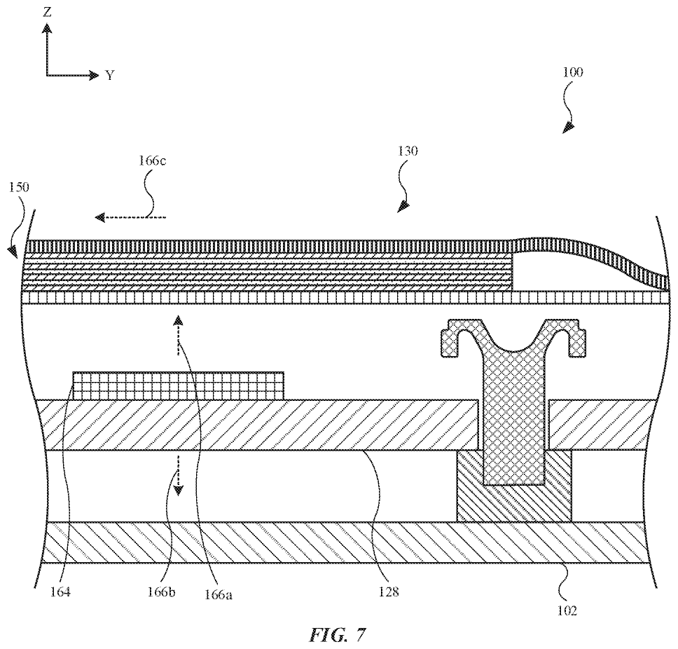

FIG. 7 illustrates a cross sectional view of electronic device 100, showing thermal energy dissipation properties of shield 130. As shown, a component 164 (such as a processing circuit or some other heat-generating component) is located on circuit board 128. The dotted lines with arrows indicate an exemplary direction of the flow of thermal energy generated by component 164. For instance, during operation, component 164 generates heat that flows along the Z-axis in both a direction 166a and a direction 166b, with direction 166b being generally opposite of direction 166a. At least some of the heat flowing in direction 166b may flow toward enclosure 102. However, although not shown, a heat dissipating body (or bodies) may be positioned between circuit board 128 (and in particular, component 164) and enclosure 102 so as to limit or prevent thermal energy from flowing through enclosure 102.

Further, at least some of the thermal energy flowing in direction 166a passes into thermal assembly 150 of shield 130. In this manner, the trajectory/direction of the thermal energy flowing into thermal assembly 150 begins to flow in a direction 166c along the Y-axis through thermal assembly 150, with the Y-axis being generally parallel to thermal assembly 150. Accordingly, thermal assembly 150 can redirect the heat to flow in a different direction, which may limit or prevent other components from receiving the thermal energy, such as display assembly 104 (shown in FIG. 1). As a result, display assembly 104 may not experience damage or other degradation due to thermal energy exposure.

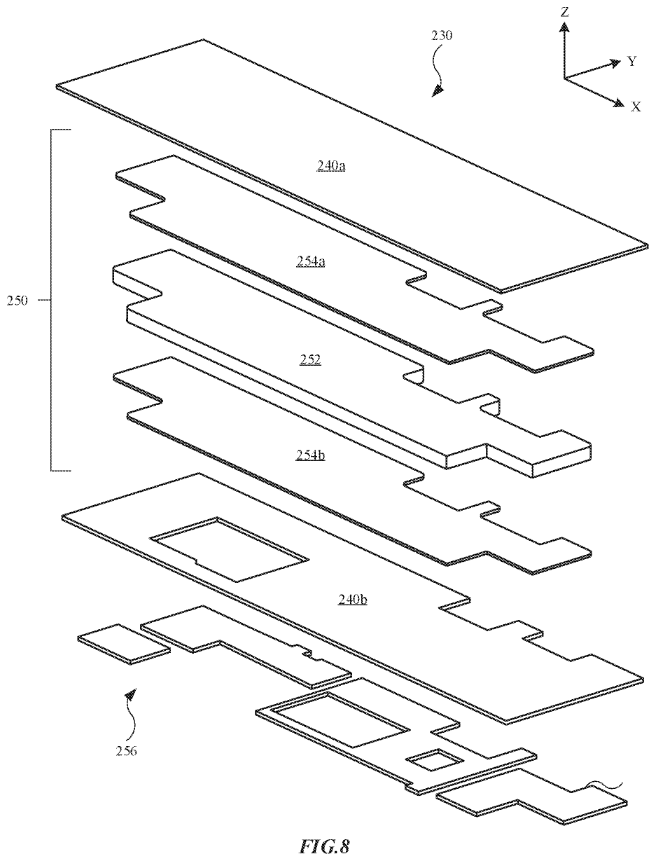

FIG. 8 illustrates an exploded view of an alternate embodiment of a shield 230, in accordance with some described embodiments. Shield 230, including its components, may include several features and materials shown and described for shield 130 (shown in FIG. 5). As shown, shield 230 includes a conductive layer 240a and a conductive layer 240b. Conductive layers 240a and 240b may define a first electrically conductive layer and a second electrically conductive layer, respectively. Accordingly, conductive layers 240a and 240b may include one or more metals, such as copper. Further, in some embodiments, conductive layers 240a and 240b are also formed from an adhesive material, such as tape.

Further, shield 230 may include a thermal assembly 250 defined by a thermally conductive layer 252. As shown, thermally conductive layer 252 represents a single thermally conductive layer. In order to maintain thermally conductive layer 252 intact, thermal assembly 250 may include an adhesive layer 254a and an adhesive layer 254b. Also, shield 230 may further include a structural layer 256 formed from one or more structural components.

Although thermal assembly 250 includes fewer thermally conductive layers as compared to thermal assembly 150 (shown in FIG. 5), the thickness (as measured along the Z-axis) of thermal assembly 250 may be greater than the combined thickness of the thermally conductive layers of thermal assembly 150. Moreover, the combined thickness of adhesive layers 254a and 254b and thermally conductive layer 252 may be the same as, or substantially similar to, the combined thickness of the thermally conducive layers and the adhesive layers of thermal assembly 150 (shown in FIG. 5). Accordingly, in some instances, shield 230 may achieve the same thermal characteristics (e.g., thermal conductivity) using a single thermally conductive layer.

It should therefore be understood that the thickness of thermal assemblies may vary based upon the number of thermally conductive layers used, which may be selected based upon required thermal characteristics and/or size and volume constraints. Also, in some embodiments, the size and shape of the conductive layers (such as conductive layers 240a and 240b) may differ from that of thermally conductive layer 252 in that each of conductive layers 240a and 240b are larger than thermally conductive layer 252. Also, while FIGS. 5 and 8 show and describe a particular number of thermally conductive layers, the number of thermally conductive layers should not be construed as limiting the number of thermally conductive layers for a thermally assembly. For example, a shield may include two or more, and even five or more, thermally conductive layers.

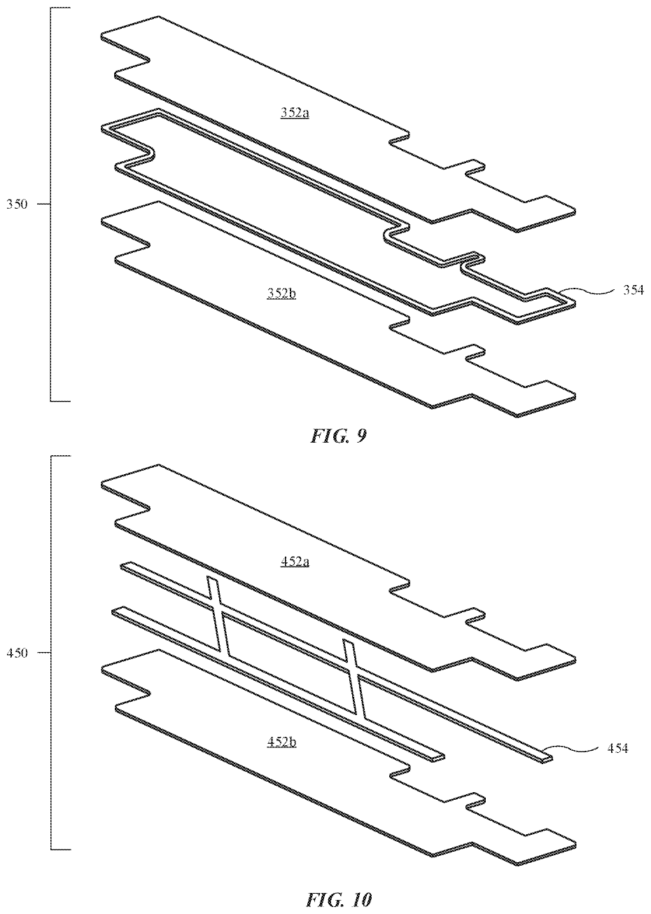

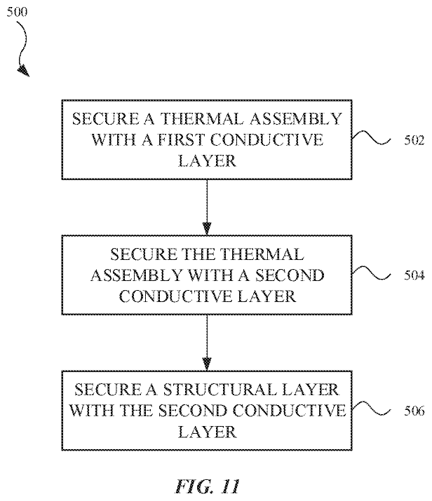

While the foregoing embodiments show and describe adhesive layers having a size and shape that generally matches the size and shape of thermally conductive layers, adhesive layers may include alternate sizes and shapes. For example, FIGS. 9 and 10 illustrate thermal assemblies with different configurations of adhesive layers. The adhesive layers shown and described in FIGS. 9 and 10 may substitute for adhesive layers in prior embodiments.

FIG. 9 illustrates an exploded view of an alternate embodiment of a thermal assembly 350. As shown, thermal assembly 350 includes a thermally conductive layer 352a and a thermally conductive layer 352b, as well as an adhesive layer 354 positioned between thermally conductive layers 352a and 352b. Adhesive layer 354 is generally an “outline” or cut out with a shape defined by the outer perimeter of either of thermally conductive layers 352a and 352b. In other words, adhesive layer 354 is not a continuous body, contrary to prior embodiments.

FIG. 10 illustrates an exploded view of an alternate embodiment of a thermal assembly 450. As shown, thermal assembly 450 includes a thermally conductive layer 452a and a thermally conductive layer 452b, as well as an adhesive layer 454 positioned between thermally conductive layers 452a and 452b. Adhesive layer 454 is generally grid with some regions extending to the outer perimeter of either of thermally conductive layers 452a and 452b. Similar to adhesive layer 354 (shown in FIG. 9), adhesive layer 454 is not a continuous body.

While FIGS. 9 and 10 show a discrete number of thermally conductive layers and adhesive layers, the number of thermally conductive layers and adhesive layers can vary in accordance with desired size and/or thermal characteristics.

FIG. 11 illustrates a flowchart 500 showing a method for assembling a shield, in accordance with some described embodiments. Flowchart 500 may be used to construct shields shown and described herein.

In step 502, a thermal assembly is secured with a first conductive layer. The thermal assembly may include one or more thermally conductive layers. Further, the thermally conductive layer(s) may include a non-metal, such as graphite. Also, the first conductive layer may include an electrically conductive tape. In this regard, the first conductive layer is generally flexible.

In step 504, the thermal assembly is secured with a second conductive layer. Also, the second conductive layer may include an electrically conductive tape. For example, the second conductive layer may include a copper tape. Similar to the first conductive layer, the second conductive layer is generally flexible. Also, in some embodiments, the second conductive layer may include a cut out, or opening, having a size and shape capable of receiving a heat-generating component, such as an integrated circuit.

In step 506, a structural layer is secured with the second conductive layer. The structure layer may include one or more structural components designed to enhance the structural rigidity of the shield. For example, the structural layer may include BoPET (as a non-limiting example) In some embodiments, the one or more structural components of the structural layer define an opening or space/void that is aligned with the cut out.

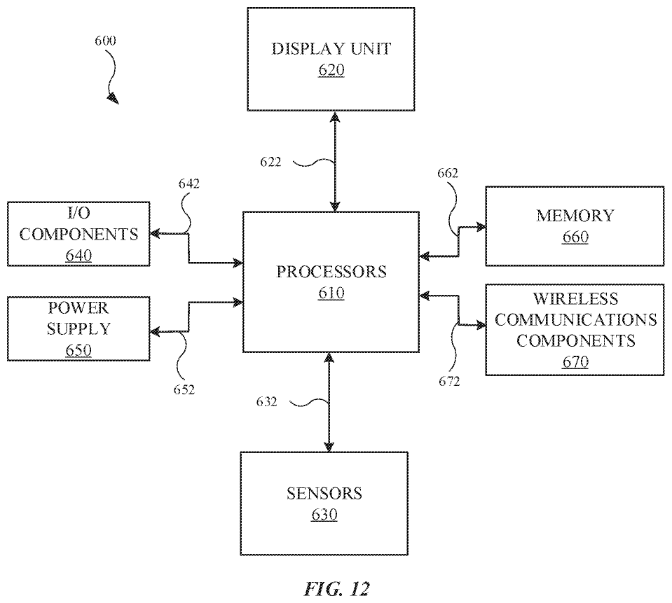

FIG. 12 illustrates a block diagram of an electronic device 600, in accordance with some described embodiments. The features in electronic device 600 may be present in other electronic devices described herein. Electronic device 600 may include one or more processors 610 for executing functions of the electronic device 600. One or more processors 610 can refer to at least one of a central processing unit (CPU) and at least one microcontroller for performing dedicated functions. Also, one or more processors 610 can refer to application specific integrated circuits.

According to some embodiments, electronic device 600 can include a display unit 620 capable of presenting a user interface that includes icons (representing software applications), textual images, and/or motion images. In some examples, each icon can be associated with a respective function that can be executed by one or more processors 610. In some cases, display unit 620 includes a display layer (not illustrated), which can include a liquid-crystal display (LCD), light-emitting diode display (LED), or the like. According to some embodiments, display unit 620 includes a touch input detection component and/or a force detection component that can be configured to detect changes in an electrical parameter (e.g., electrical capacitance value) when the user's appendage (acting as a capacitor) comes into proximity with display unit 620 (or in contact with a transparent layer that covers display unit 620). Display unit 620 is connected to one or more processors 610 via one or more connection cables 622.

According to some embodiments, electronic device 600 can include one or more sensors 630 capable of providing an input to one or more processors 610 of electronic device 600. One or more sensors 630 may include a temperature sensor, as a non-limiting example. One or more sensors 630 is/are connected to one or more processors 610 via one or more connection cables 632.

According to some embodiments, electronic device 600 can include one or more input/output components 640. In some cases, one or more input/output components 640 can refer to a button or a switch that is capable of actuation by the user. When one or more input/output components 640 is/are used, one or more input/output components 640 can generate an electrical signal that is provided to one or more processors 610 via one or more connection cables 642.

According to some embodiments, electronic device 600 can include a power supply 650 that is capable of providing energy to the operational components of electronic device 600. In some examples, power supply 650 can refer to a rechargeable battery. Power supply 650 can be connected to one or more processors 610 via one or more connection cables 652. Power supply 650 can be directly connected to other devices of electronic device 600, such as one or more input/output components 640. In some examples, electronic device 600 can receive power from another power sources (e.g., an external charging device) not shown in FIG. 10.

According to some embodiments, electronic device 600 can include memory 660, which can include a single disk or multiple disks (e.g., hard drives), and includes a storage management module that manages one or more partitions within memory 640. In some cases, memory 660 can include flash memory, semiconductor (solid state) memory or the like. Memory 660 can also include a Random Access Memory (“RAM”) and a Read-Only Memory (“ROM”). The ROM can store programs, utilities or processes to be executed in a non-volatile manner. The RAM can provide volatile data storage, and stores instructions related to the operation of the electronic device 600. In some embodiments, memory 660 refers to a non-transitory computer readable medium. One or more processors 610 can also be used to execute software applications. In some embodiments, a data bus 662 can facilitate data transfer between memory 660 and one or more processors 610.

According to some embodiments, electronic device 600 can include wireless communications components 670. A network/bus interface 672 can couple wireless communications components 670 to one or more processors 610. Wireless communications components 670 can communicate with other electronic devices via any number of wireless communication protocols, including at least one of a global network (e.g., the Internet), a wide area network, a local area network, a wireless personal area network (WPAN), or the like. In some examples, wireless communications components 670 can communicate using NFC protocol, BLUETOOTH® protocol, or WIFI® protocol.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An electronic device, comprising:
a circuit board that carries a processing circuit; and
a shield that covers the processing circuit, the shield comprising:
an electrically conductive layer configured to block radio interference generated by the processing circuit,
a thermal assembly coupled with the electrically conductive layer, the thermal assembly configured to dissipate thermal energy generated by the processing circuit, the thermal assembly comprising:
a first thermally conductive layer,
an adhesive layer coupled with the first thermally conductive layer, and
a second thermally conductive layer coupled with the adhesive layer, wherein the first thermally conductive layer and the second thermally conductive layer comprise a non-metal material.

2. The electronic device of claim 1, wherein the electrically conductive layer comprises an electrically conductive tape.

3. The electronic device of claim 2, wherein:
the electrically conductive tape defines a first electrically conductive tape,
the thermal assembly further comprises a second electrically conductive tape, and
the thermal assembly is positioned between the first electrically conductive tape and the second electrically conductive tape.

4. The electronic device of claim 3, further comprising a metal wall located on the circuit board, wherein at least the second electrically conductive tape is adhered to the metal wall.

5. The electronic device of claim 3, wherein the second electrically conductive tape comprises a copper tape.

6. The electronic device of claim 3, wherein each of the first electrically conductive tape, the second electrically conductive tape, and the thermal assembly lacks an opening.

7. The electronic device of claim 1, wherein the thermal assembly further comprises:
a second adhesive layer coupled with the second thermally conductive layer;
a third thermally conductive layer adhered to the second adhesive layer;
a third adhesive layer coupled with the third thermally conductive layer; and
a fourth thermally conductive layer coupled with the third adhesive layer, wherein the third thermally conductive layer and the fourth thermally conductive layer comprise the non-metal material.

8. The electronic device of claim 7, wherein each of the first thermally conductive layer, the second thermally conductive layer, and the third thermally conductive layer include a first size, and the fourth thermally conductive layer include a second size less than the first size.

9. An electronic device, comprising:
a display configured to present visual information; and
an enclosure coupled with the display, the enclosure defining an internal volume configured to carry components, the components comprising:
a circuit board that carries a processing circuit,
an antenna electrically coupled to the circuit board,
a metal wall located on the circuit board, and
a shield comprising:
a conductive tape adhered to the metal wall, the conductive tape configured to shield the antenna from radio frequency shield generated by the processing circuit, and
a thermal assembly adhered with the conductive tape, the thermal assembly providing a thermal dissipation path for thermal energy generated by the processing circuit.

10. The electronic device of claim 9, wherein the thermal assembly comprises a non-metal material.

11. The electronic device of claim 10, wherein the non-metal material comprises graphite.

12. The electronic device of claim 9, wherein the thermal assembly comprises:
a first graphite layer coupled with the conductive tape;
a first adhesive layer adhered to the first graphite layer;
a second graphite layer coupled with the first adhesive layer;
a second adhesive layer adhered to the second graphite layer; and
a third graphite layer coupled with the second adhesive layer.

13. The electronic device of claim 12, further comprising:
a third adhesive layer adhered to the third graphite layer;
a fourth graphite layer coupled with the third adhesive layer; and
a second conductive tape adhered to the fourth graphite layer.

14. The electronic device of claim 13, wherein each of the first graphite layer, the second graphite layer, and the third graphite layer includes a first size, and the fourth graphite layer includes a second size less than the first size.

15. The electronic device of claim 9, wherein the shield is secured with the metal wall only through the conductive tape.

16. A shield suitable for use in an electronic device, the shield comprising:
a first electrically conductive tape;
a second electrically conductive tape that is adhered to the first electrically conductive tape; and
a thermal assembly positioned between the first electrically conductive tape and the second electrically conductive tape, the thermal assembly comprising:
a first thermally conductive layer,
a first adhesive layer adhered to the first thermally conductive layer,
a second thermally conductive layer adhered to the first adhesive layer, and
a second adhesive layer adhered to the second thermally conductive layer, wherein the first thermally conductive layer and the second thermally conductive layer comprise a non-metal material.

17. The shield of claim 16, wherein the thermal assembly further comprises:
a second adhesive layer that is coupled with the second thermally conductive layer,
a third thermally conductive layer adhered to the second adhesive layer,
a third adhesive layer coupled with the third thermally conductive layer, and
a fourth thermally conductive layer coupled with the third adhesive layer, wherein the third thermally conductive layer and the fourth thermally conductive layer comprise the non-metal material.

18. The shield of claim 17, wherein the non-metal material comprises graphite.

19. The shield of claim 16, wherein each of the first thermally conductive layer and the second thermally conductive layer is free of openings.

20. The shield of claim 19, wherein each of the first electrically conductive tape and the second electrically conductive tape is free of openings.
